(19) United States
(12) Patent Application Publication
(10) Pub. No.: US 2015/0096606 A1
(43) Pub. Date: Apr. 9, 2015

(54) METHOD FOR PRODUCING A PHOTOVOLTAIC MODULE WITH AN ETCHING STEP P3 AND AN OPTIONAL STEP P2

(71) Applicant: COMMISSARIAT A L'ENERGIE ATOMIQUE ET AUX ENERGIES ALTERNATIVES, PARIS (FR)

(72) Inventors: Nicolas Karst, Folkling (FR); Charles Roger, Joue Les Tours (FR)

(21) Appl. No.: 14/390,509

(22) PCT Filed: Apr. 2, 2013
(86) PCT No.: PCT/IB2013/052613

§ 371 Date: Oct. 3, 2014

(30) Foreign Application Priority Data
Apr. 6, 2012 (FR) 12 53202

(51) Int. Cl. H01L 31/05; H01L 31/0296; H01L 31/18

(52) U.S. Cl. CPC H01L 31/0504; H01L 31/1828; H01L 31/0296
USPC 136/244; 438/80

(57) ABSTRACT

The present invention concerns a method for producing an intermediate product for obtaining a photovoltaic module comprising a plurality of solar cells, said method comprising the following steps: (a) localised deposition on a substrate (4) of a layer (7) of an Se or S material, so as to cover at least one portion (400) of the substrate, (b) deposition on this localised layer (7), of a layer (41) of conductive material, said layer coating the localised layer.

The invention relates to the field of photovoltaic solar energy and more particularly to photovoltaic modules in the form of thin layers.

Within the framework of the present patent application, a “thin layer” will be a layer exhibiting a thickness of less than 5 μm.

A photovoltaic module comprises several solar cells placed in series. Indeed, the electrical voltage generated across the terminals of a single solar cell, less than 1 volt, is in general too low for many devices. It is therefore necessary for many cells to be placed in series. Thus, the voltage delivered by a photovoltaic module is of the order of 100 volts, for some hundred cells linked in series.

For photovoltaic modules in the form of thin layers, this series placement can be obtained by steps of etching and of deposition carried out on one and the same substrate. A monolithic interconnection is thus produced. This exhibits a considerable advantage with respect to the conventional technology of bulk crystalline silicon. Indeed, the production of modules made of crystalline silicon requires unwieldy and laborious wire connection and soldering operations. All these operations are rendered irrelevant with thin layer technology.

The method of monolithic interconnection of solar cells in the form of thin layers requires three etching steps, conventionally dubbed P1, P2, P3.

The first step (P1) ensures the electrical insulation of two adjacent cells at the level of the rear-face electrode of the solar cells.

The second step (P2) makes it possible to connect the front-face electrode of a given cell to the rear-face electrode of the adjacent cell.

The third step (P3) consists in electrically insulating two adjacent cells at the level of the front-face electrode.

Various techniques are implemented to carry out this monolithic interconnection method.

The most conventional are mechanical etching or laser ablation.

It is thus possible to refer to document U.S. Pat. No. 4,502,225 which describes a device comprising an etching tip intended for semi-conducting devices.

Laser use in thin-layer solar cells is in particular described in the articles “Selective ablation of thin films with short and ultrashort laser pulses”, Hermann et al., Appl. Surf. Sci. 252 (2006) 4814 or else “Laser applications in thin-film photovoltaics”, Bartolme et al., Appl Phys B 100 (2010) 427-436.

These etching techniques exhibit the advantage of being able to be employed for a wide variety of materials deposited in thin layers, such as for example CdTe, a-Si, CZTS (of general formula Cu₂ZnSn(S,Se)₄) or CIGS (of general formula Cu(In, Ga)(Se, S)₂).

However, these etching techniques each exhibit drawbacks.

Thus, mechanical etching leads to damage to the materials on account of the presence of mechanical stresses on the layers, to the formation of debris on the surface of the layers in proximity to the etching line which may lead to problems of short-circuiting, as well as to the wearing of the etching tips. Moreover, generally, the quality of mechanical etching is very sensitive to many parameters such as the morphology or the properties of the thin layers, as well as to the operating parameters of the etching tips.

Moreover, laser ablation is not simple to implement. Indeed, it may be noted that the material removed may melt and partly clog up the groove produced by the laser ablation. Thus, this technique does not make it possible to obtain a clean surface necessary for producing good quality electrical contact.

It is also possible to use chemical etching processes. However, these processes are more complicated and more expensive to implement than the conventional processes of mechanical etching or laser ablation.

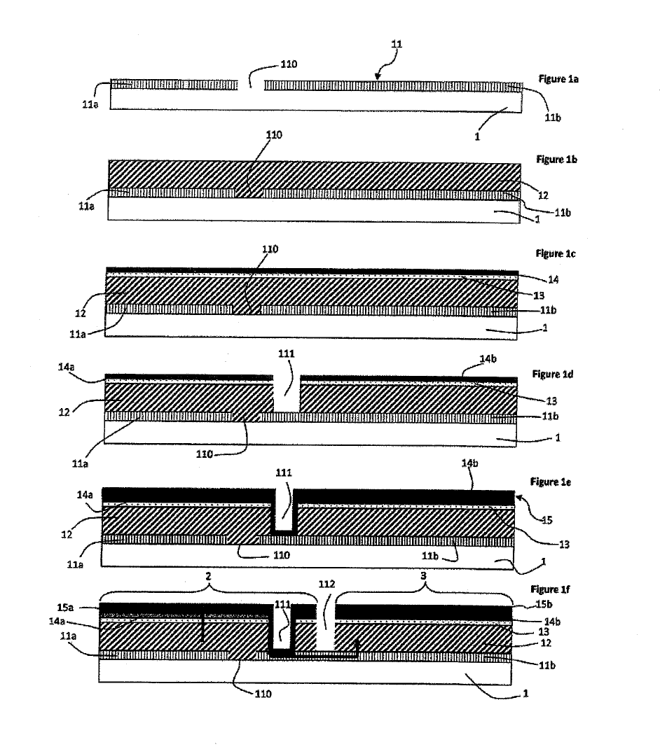

In order to better pinpoint the context of the invention, a conventional method of monolithic interconnection for a photovoltaic module in the form of thin layers will now be described with reference to FIGS. 1a to 1f. All these figures are sectional views and represent various steps of implementation of this method.

FIG. 1a represents a substrate 1 which can be made of diverse materials, in particular glass, or else plastic or metal (for example steel, aluminum, or titanium), and can be flexible or rigid.

In general, this substrate is made of soda-lime glass whose thickness is a few millimeters and typically between 1 and 3 mm.

On this substrate 1 is deposited a molybdenum layer 11 whose thickness is generally between 100 nm and 2 μm, and preferably of the order of 1 μm.

This molybdenum layer will serve to constitute the rear-face electrode of the various cells forming the photovoltaic module.

FIG. 1a shows that an etching step is carried out after the deposition of the Mo layer. As indicated previously, this etching is generally carried out, either mechanically, or by laser ablation. It leads to the formation of a groove 110, devoid of molybdenum.

This groove 110 makes it possible to define the rear-face electrodes 11a and 11b of the adjacent cells 2 and 3 illustrated in FIG. 1f.

This etching step corresponds to step P1 mentioned previously.

The width of the groove 110 is generally between 10 μm and 100 μm, and it is preferably of the order of 50 μm.

FIG. 1b illustrates another step of the method in which there is produced a photovoltaic layer and, by way of example, a crystallized CIGS layer. This layer has a light-absorbing function.

This step consists firstly in introducing, on the rear-face electrode 11, metallic precursors of Cu, In, Ga, and elements of type Se and/or S, serving for the growth of the layer of CIGS, a p-type semiconductor.

Numerous deposition methods suitable for thin layers can be used.

These may be vacuum methods, such as cathodic evaporation or sputtering or methods implemented at atmospheric pressure, such as electrodeposition, silk-screen printing, doctor-blading, ink-jet or slit-coating.

Thus, precursors of Cu, In and Ga can be deposited by cathodic sputtering. A layer of Se and/or S can thereafter be deposited on the obtained stack by a vacuum process or a process implemented at atmospheric pressure.

Generally, a bulk introduction of S or Se is always necessary. The chalcogen S or Se can be introduced in the form of elementary gas, in the form of gas (H₂S or H₂Se) or in the form of a layer of evaporated S or Se, deposited on the surface of the layer of metallic precursors.

It should be noted that the gases H₂S and H₂Se are highly toxic, thereby greatly complicating their use on an industrial scale.

The thickness of this layer of metallic precursors is generally between 300 nm and 1 μm.

The conversion of the constituents into a layer 12 of crystallized CIGS is performed by high-temperature annealing, dubbed selenization/sulfurization annealing, using a temperature rise ramp of between 1° C./s and 10° C./s.

It is in particular possible to refer to document U.S. Pat. No. 5,578,503 which describes a method for obtaining a semi-conductor of the type CuXY₂ where X is In and/or Ga and Y is Se or S.

This method comprises an annealing with a fast heating step with a temperature ramp of at least 10° C./s so as to attain a temperature of greater than or equal to 350° C., this temperature being thereafter maintained for a duration of between 10 seconds and 1 hour.

In practice, the temperature is generally between 400 and 600° C. and, preferably, equal to about 500° C.

The layer of constituents can be covered with a cap, preferably made of graphite. This cap makes it possible to ensure a more significant partial pressure of Se and/or S during annealing, thereby leading to an increase in the diffusion of Se and/or S in the metallic precursors.

It is also possible to refer to document U.S. Pat. No. 5,436,204 which describes a method comprising three steps:

a first step of depositing indium and/or gallium at a temperature of between 350 and 500° C., a second step of depositing copper in which the temperature is increased so as to attain a higher recrystallization temperature of between 500 and 600° C., and a third step of depositing indium and/or gallium in which this higher temperature is maintained. It should be noted that the whole of this method is carried out in a selenium and/or sulfur atmosphere.

FIG. 1c shows another step of implementation of the method, in which a n-type semi-conductor layer 13 is deposited on the layer of CIGS, so as to form the pn junction.

This layer can be deposited by chemical bath, by cathodic sputtering or else by evaporation.

It may for example be composed of CdS and deposited by chemical bath, the layer 13 exhibiting a thickness of a few tens of nm.

Other materials can be used such as ZnS or Zn(O,S), for a thickness for example of between 5 nm and 30 nm.

FIG. 1c also illustrates another, optional, step of the method. This step consists in depositing a layer 14 of intrinsic ZnO, whose function will be explained further on.

This layer 14 is highly transparent in the solar spectrum and highly resistive. It is generally deposited by cathodic sputtering and exhibits a thickness of a few tens of nm.

It may be noted that the layer 13 prevents reactions between the ZnO and the CIGS and thus protects the layer 12, during deposition of the layer 14.

FIG. 1d illustrates a step of implementation of the method in which another etching is carried out, either mechanically, or by laser ablation.

This etching, corresponding to step P2 mentioned above, consists in removing all the layers previously deposited on the molybdenum layer 11. This etching therefore makes it possible to produce an opening referenced 111 in FIG. 1d. It will make it possible to produce a part (P2) of the electrical interconnection between two adjacent cells.

The width of the opening 111 is generally between 50 μm and 150 μm and it is preferably equal to about 100 μm.

Moreover, the distance between the openings 110 and 111 is generally between 50 μm and 150 μm and it is preferably equal to about 100 μm.

FIG. 1e illustrates yet another step of implementation of the method, in which a layer of a conducting transparent oxide 15 is deposited.

This layer can be deposited by cathodic sputtering and exhibit a thickness of a few hundred nm.

It may in particular be Al-doped ZnO, exhibiting a thickness of about 500 nm.

This layer of Al-doped ZnO will serve to form a conducting transparent electrode referenced 15a for the front-face electrode of the cell 2 and 15b for the front-face electrode of the cell 3 (see FIG. 1f).

It is generally admitted that the n-type semi-conductor layer 13 may exhibit discontinuities. The function of the layer 14 of ZnO is then to ensure electrical insulation between the conducting transparent layer 15 and the layer 12 of CIGS.

Other materials, such as the tin-doped indium oxide (ITO), silver nanowires, carbon nanotubes could also be employed to produce this conducting transparent electrode. Likewise, other deposition techniques could also be used.

It is understood that the distance between the openings 110 and 111 must be significant enough to avoid too significant an interconnection resistance between the front-face electrode 15a of the cell 2 and the rear-face electrode 11b of the cell 3.

FIG. 1f illustrates a last step of the method, in which another etching is carried out in the stack of layers, so as to definitively insulate the cell 2 from the cell 3.

This etching step corresponds to step P3 mentioned above. It can be carried out mechanically or by laser ablation and consists in removing all the layers deposited on the rear-face electrode 11b.

The opening 112 obtained makes it possible to electrically insulate the two cells 2 and 3 at the level of their front-face electrodes 15a and 15b.

The opening 112 more generally exhibits a width of between 10 μm and 200 μm, and it is preferably of the order of 100 μm.

FIG. 1f also illustrates the path of the charges between the two adjacent cells 2 and 3.

Thus, the front-face electrode 15a of the first cell 2 makes it possible to collect at the front face the electrical charges generated in this cell 2 and to convey them to the rear-face electrode 11b of the adjacent cell 3.

Having regard to the drawbacks exhibited by the conventional etching techniques, solutions have been proposed in the prior art.

However, they relate essentially to step P2.

Their object is to locally increase the conductivity of the CIGS material so as to carry out the conduction of the charges from the front-face electrode of a given cell to the rear-face electrode of the adjacent cell.

This may involve a laser treatment making it possible for the GIGS to be afforded metallic behavior locally. It is in particular possible to refer to the article by Westin et al., “Laser patterning of P2 interconnect via thin-film CIGS PV modules”, Solar Energy Materials and Solar Cells 92 (2008) 1230. Locally deposited metallic precursors can also play this role by diffusing in the layer of GIGS. It is in particular possible in this regard to refer to document US-2010/0000589.

On the other hand, to date no other methods exist for carrying out the etching P1, apart from mechanical, laser or optionally chemical etching.

The object of the invention is therefore to alleviate the drawbacks of this type of etching by proposing another method making it possible to electrically insulate two solar cells which are adjacent at the level of their rear-face electrodes, while avoiding the need to carry out mechanical, laser or chemical etching.

Thus, the invention relates firstly to a method for producing an intermediate product for obtaining a photovoltaic module comprising a plurality of solar cells, this method comprising the following steps:

(a) the localized deposition on a substrate of a layer of a material of the type Se or S, so as to cover at least one part of the substrate,
(b) the deposition, on this localized layer, of a layer of conducting material, this layer coating the localized layer.

In a variant, during step (a), a metal layer is also deposited locally on the substrate so as to cover at least one part of the substrate, distinct from said at least one part covered with a material of the type Se or S.

The invention also relates to a method for obtaining a photovoltaic module comprising a plurality of solar cells in a structure in the form of thin layers, which successively comprises a substrate, a rear-face electrode, a photovoltaic layer obtained by annealing on the basis of metallic precursors and a semi-conductor layer, in which:

an intermediate product is produced in accordance with the method according to the invention, the layer of conducting material forming the rear-face electrode,

an annealing step is carried out, which modifies said localized layer of material of the type Se or S so as to form, in the rear-face electrode, a zone exhibiting a more significant resistivity than the remainder of the rear-face electrode, this zone ensuring the electrical insulation between two adjacent cells of the photovoltaic module.

This method therefore makes it possible to avoid the implementation of an etching step of the type P1.

In a first variant, the annealing step is carried out before the obtaining of the photovoltaic layer, with a temperature ramp of less than or equal to 1° C./s and at a temperature of between 225 and 300° C., for a duration of between 1 and 5 min, said zone of the rear-face electrode being formed of a material resulting from the reaction of the conducting material with Se or S.

In other variants, the annealing step is carried out during the obtaining of the photovoltaic layer, at a temperature of between 400 and 650° C., with temperature ramps of strictly greater than 1° C./s and possibly as much as 15° C./s.

Thus, in a second variant, said zone is formed of photovoltaic material.

In a third variant, said zone is a groove.

In another mode of implementation, the method according to the invention consists in producing the intermediate product in accordance with the variant according to the invention, according to which, during step (a), a layer of a metal is also deposited locally on the substrate, so as to cover at least one part of the substrate, distinct from said at least one part covered with a material of the type Se or S.

In this case, the obtaining of the photovoltaic layer leads moreover to the formation, in this layer, of a zone made of a conducting material, this zone producing the electrical connection between the front-face electrode of a cell and the rear-face electrode of an adjacent cell of the photovoltaic module.

In this variant, the method according to the invention also makes it possible to avoid the implementation of an etching step of type P2.

The invention also relates to a photovoltaic module comprising a plurality of solar cells connected in series on a common substrate, each cell comprising a front-face electrode, transparent to light, and a rear-face electrode, spaced apart from the front-face electrode by a photovoltaic layer and another layer of semi-conductor, making it possible to create a pn junction with the photovoltaic layer, in which the rear-face electrodes of two adjacent cells are insulated electrically by a zone of the rear-face electrode which is situated between the two cells and which exhibits a more significant resistivity than the remainder of the rear-face electrode.

In a first variant, said zone is formed of a material resulting from the reaction of the conducting material of the rear-face electrode with an element picked from Se and S.

In a second variant, this zone is formed of the same material as the photovoltaic layer.

In a third variant, this zone is a groove.

In another embodiment, the photovoltaic module according to the invention also comprises, in the photovoltaic layer and between two adjacent cells, a zone made of a conducting material which produces the electrical connection between the front-face electrode of a cell and the rear-face electrode of an adjacent cell.

The invention also relates to an intermediate product for obtaining a photovoltaic module according to the invention, comprising successively on a substrate, a localized layer of Se or S and a layer of conducting material coating this localized layer.

The intermediate product making it possible to obtain the other embodiment of the photovoltaic module according to the invention also comprises, on the substrate, a localized layer of a metal which is distinct from the localized layer of Se or S.

The invention will be better understood and other aims, advantages and characteristics of the latter will be more clearly apparent on reading the description which follows and which is given in regard to the appended drawings in which:

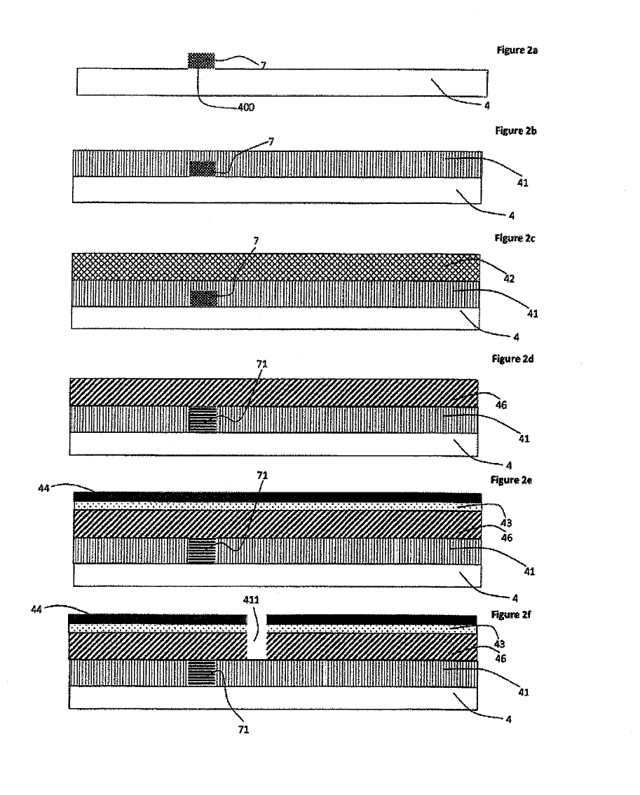

FIGS. 2a to 2h represent various steps of implementation of the method according to the invention,

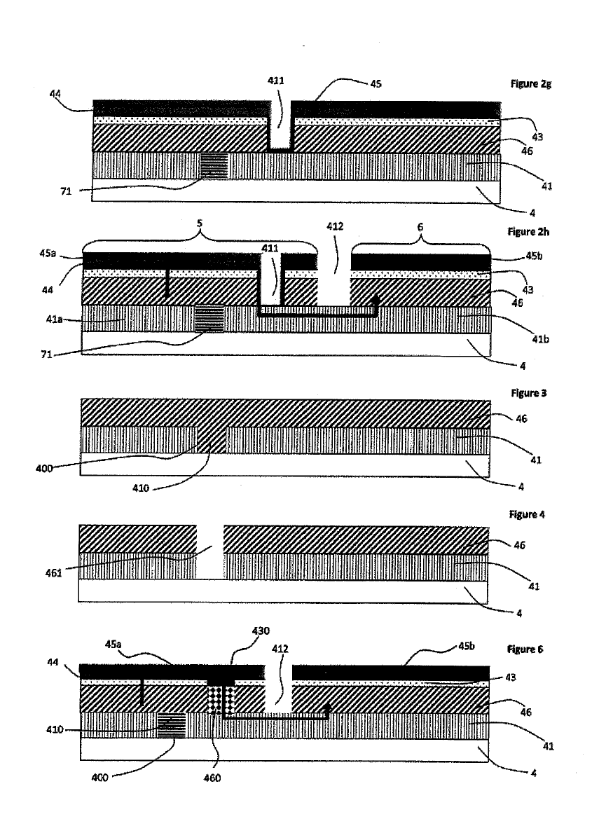

FIGS. 3 and 4 illustrate variants of a step of the method according to the invention, corresponding to FIG. 2d,

FIGS. 5a to 5f represent various steps of implementation of another method according to the invention, and

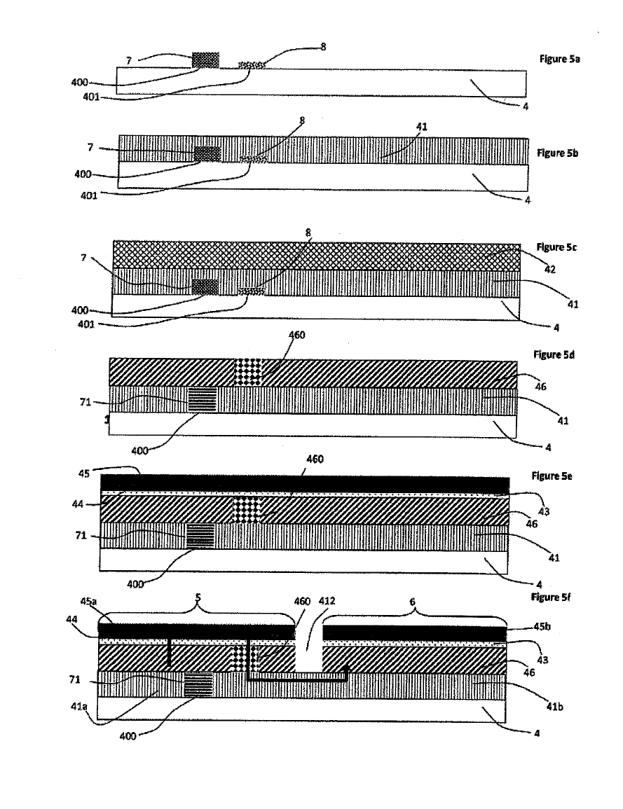

FIG. 6 represents a variant of the method illustrated in FIGS. 5a to 5f.

All these figures are sectional views and the elements common to the various figures will be designated by the same references.

FIG. 2a represents a substrate 4 which can be made of diverse materials, conventionally glass, plastic or metal. In general, this substrate is made of soda-lime glass whose thickness is a few millimeters and, for example, 3 mm.

On this substrate 4 is deposited a layer 7 of selenium or sulfur in a localized manner.

Thus, at least one part 400 of the substrate is covered with a material of the type Se or S.

FIG. 2a shows only a single part 400 of the substrate 4 covered with a material of the type Se or S. Of course, several parts of the substrate will be able to be covered with a material of the type Se or S, insofar as a plurality of photovoltaic cells are intended to be produced on the substrate 4.

Various deposition methods can be implemented to produce the localized layer 7.

Thus, this layer can be deposited by vacuum evaporation through a mechanical mask. In this case, this may involve an electrodeposited nickel mask comprising a number of slots which is dependent on the number of cells of the photovoltaic module to be produced. Each slot can exhibit a width of between 50 and 150 μm, and preferably equal to 100 μm.

The layer 7 can also be obtained by a printing process, of the slit-coating, silk-screen printing or ink-jet type, using for example an ink based on nanoparticles of Se or S dispersed in an organic solvent.

Such a printing process is, preferably, used since its implementation gives rise to lower costs than those of a vacuum implementation process.

FIG. 2b illustrates another step of the method in which a metallic layer 41 forming a rear-face electrode for the various cells of the photovoltaic module which will be obtained by the method according to the invention is deposited on the substrate 4.

This layer 41 is continuous; it therefore covers the substrate 4 in a uniform manner.

This layer is for example made of molybdenum and its thickness is between 100 nm and 2 μm and in particular equal to 500 nm.

The deposition of the molybdenum layer can in particular be carried out by cathodic sputtering.

As shown by FIG. 2b, the metallic layer 41 coats the localized layer 7 of Se or S.

The stack illustrated in FIG. 2b constitutes an intermediate product which can be produced independently of the steps of the method which are implemented subsequently.

In practice, this intermediate product will be able to be produced by the industry fabricating the substrate 4.

FIG. 2c illustrates a step of the method in which the precursors, which will lead to the formation of the photovoltaic layer, are introduced in the form of a layer 42.

These are metallic precursors of Cu, In, Ga or else metallic precursors of Cu, Zn, Sn, and optionally at least one element picked from Se and S.

By way of example, the ratios of the elements Cu, In and Ga are conventionally chosen in such a way that:

0.75≦Cu/(In+Ga)≦0.95; 0.55≦In/(In+Ga)≦0.85 and 0.15≦Ga/(In+Ga)≦0.45

The ratios of the elements Cu, Zn and Sn are themselves conventionally chosen in such a way that:

0.75≦Cu/(Zn+Sn)≦0.95 and 1.05≦Zn/Sn≦1.35.

This layer 42 can essentially comprise metallic precursors. In this case, the sulfur or the selenium are then introduced in gaseous form. They can also be introduced in the form of a layer deposited on the layer of metallic precursors.

Moreover, the layer 42 can comprise at one and the same time metallic precursors and selenium or sulfur.

FIG. 2d illustrates another step of the method in which at one and the same time the localized layer 7 and the layer 42 are transformed.

Firstly, a step of annealing at a moderate temperature is performed. This annealing step comprises a rise in temperature with ramps of less than or equal to 1° C./s and preferably of the order of 0.1° C./s, so as to attain a temperature of between 225 and 300° C. and preferably, of the order of 250° C. The stack is subjected to this temperature for a duration of between 1 and 5 min.

This annealing step can be performed in a vacuum or in a neutral atmosphere.

Thus, the selenium will react with the molybdenum layer 41 to form MoSe₂ in the layer 41 at the level of the part 400 of the substrate. The MoSe₂ grows in a hexagonal close packed structure whose c axis is parallel to the surface of the layer 41.

In another form of implementation, it is the sulfur present in the layer 7 which reacts with the molybdenum layer 41 to form MoS₂.

The thickness of the molybdenum layer and the quantity of selenium or sulfur, introduced by the layer 7, will be tailored so that the molybdenum is transformed into MoSe₂ or MoS₂, over the whole thickness of the layer 41.

Thus, by virtue of this annealing step, a zone 71 formed of MoSe₂ or MoS₂ is formed in the molybdenum layer 41.

By way of example, for a thickness of the molybdenum layer of about 500 nm, the thickness of the selenium layer 7 will be between 1 and 2 μm with a width of between 50 and 150 μm and preferably equal to 100 μm, according to the porosity of the molybdenum layer, so as to correspond to the theoretical stoichiometry of the MoSe₂. In a preferred manner, when the molybdenum layer exhibits zero porosity, the thickness of the selenium layer 7 will be about 1.8 μm. This thickness will be about 1 μm when the layer 7 is made of sulfur.

The resistivity of MoSe₂ or of MoS₂ in the direction parallel to the c axis is much more significant than that of molybdenum. Indeed, the resistivity ratio is greater than 10. The zone 71 of the layer 41 therefore exhibits a more significant resistivity than the remainder of the layer 41 which will constitute the rear-face electrode of the cells of the photovoltaic module.

This zone 71 will thus make it possible to define the rear-face electrodes 41a and 41 b of two adjacent cells, referenced 5 and 6 in FIG. 2h, and to insulate them electrically.

The formation of this zone 71 of the rear-face electrode exhibiting a greater resistivity makes it possible to avoid the etching step P1 and therefore to eliminate the drawbacks related to this etching step.

FIG. 2d illustrates a mode of implementation of the method in which the annealing step leading to the formation of the zone 71 of greater resistivity is integrated into the annealing method by virtue of which the metallic precursors present in the layer 42 are converted into a layer 46 of photovoltaic material, for example CIGS or CZTS, by virtue of the introduction of selenium or sulfur. Thus, a material of the CZTS type may in particular consist of Cu₂ZnSnSe₄, Cu₂ZnSnS₄ or Cu₂ZnSn(S,Se)₄, depending on whether selenium, sulfur, or a mixture of the two components, is introduced.

In practice, the conversion of the metallic precursors begins during the step of annealing at moderate temperature. Thus, various compounds based on Cu, Ga and Se form. However, the complete conversion into CIGS or CZTS is not achieved.

In this mode of implementation, the annealing step leading to the formation of MoSe₂ or of MoS₂ having been carried out, the temperature of the substrate 4 is further increased to carry out a higher-temperature annealing allowing the crystallization (transformation) of the metallic precursors into CIGS or CZTS. This is typically between 400 and 650° C. and, preferably, equal to 550° C. The range of values for the temperature rise ramp is between 1° C./s and 15° C./s.

In a conventional manner, the introduction of selenium or sulfur can be performed during the annealing in gaseous form or, before the annealing, during the deposition of a selenium or sulfur layer on the layer of metallic precursors or else during the deposition of the layer of metallic precursors. In the latter case, the annealing is performed in a neutral atmosphere.

Moreover, it is also usual to comply with an over-stoichiometry in Se of about 40% knowing that the theoretical stoichiometry of Cu(In,Ga)Se₂ is such that Se/Cu=2. The same holds when the metallic precursors chosen lead to the formation of CZTS.

In a conventional manner, the duration of the annealing is between 30 seconds and 30 minutes and it is, preferably, about 1 min in duration.

In this regard, reference is made to the teaching of the previously mentioned documents U.S. Pat. No. 5,578,503 and U.S. Pat. No. 5,436,204.

In the case of the method for forming CIGS described in document U.S. Pat. No. 5,578,503, the step of annealing at moderate temperature, leading to the formation of the zone 71 in the layer 41, is indeed carried out after the deposition of the layer 42 comprising metallic precursors.

This annealing step is then carried out after the method step illustrated in FIG. 2c.

However, in the case of the method for forming CIGS described in document U.S. Pat. No. 5,436,204, the annealing step leading to the formation of the zone 71 in the layer 41 is carried out before the deposition of the layer 42.

Stated otherwise, this annealing step is then carried out between the method steps illustrated in FIGS. 2b and 2c.

FIGS. 2e to 2h describe the other steps of the method according to the invention, which are similar to those described with reference to FIGS. 1c to 1f.

Thus, FIG. 2e shows an implementation step in which an n-type semi-conductor layer 43 is deposited on the layer 46, so as to form the pn junction. As indicated in regard to FIG. 1c, the material used may be CdS, ZnS or Zn(O,S).

FIG. 2e illustrates another, optional, step of the method which consists in depositing a layer 44 of a transparent material on the layer 43. As indicated previously in regard to FIG. 1c, the material used may be ZnO.

FIG. 2f illustrates an etching step corresponding to step P2 mentioned previously (FIG. 1d).

It consists in removing all the layers previously deposited on the layer 41, aside, however, from the zone 71 of higher resistivity.

This etching makes it possible to produce an opening referenced 411 in FIG. 2f, and therefore a part of the electrical interconnection between the two adjacent cells referenced 5 and 6 in FIG. 2h.

This etching step corresponds to step P2 (FIG. 1d).

Preferably, the zone 71 and the opening 411 are situated at a minimum distance of between 50 μm and 150 μm, and in particular of the order of 100 μm.

FIG. 2g illustrates another implementation step, in which a layer of a transparent and conducting oxide 45 is deposited on the layer 44 or directly on the layer 43 when the layer 44 is omitted.

This may in particular be Al-doped ZnO.

The thickness of the layer 45 is between 100 and 800 nm and, preferably, equal to about 500 nm.

Finally, FIG. 2h illustrates a last step of the method, in which another etching is carried out in the stack of layers.

This etching step corresponds to step P3 (FIG. 10.

The opening 412 obtained is yet further distant from the zone 71 than the opening 411. It makes it possible to electrically insulate the two cells 5 and 6, at the level of their front-face electrodes 45a and 45b.

It is noted that the two cells 5 and 6 are spaced apart by the zone 71 and the openings 411 and 412. This space is the interconnection zone.

Generally, the indications given in respect of the implementation of the steps illustrated in FIGS. 1c to 1f are also valid in respect of the steps illustrated in regard to FIGS. 2e to 2h.

FIG. 2h also illustrates the path of the charges between two adjacent cells 5 and 6.

Thus, the front-face electrode 45a of the first cell 5 makes it possible to collect, at the front face, the electrical charges generated in this cell 5 and to convey them to the rear-face electrode 41b of the adjacent cell 6.

The method which has just been described exhibits the advantage of eliminating one of the etching steps conventionally envisaged in monolithic interconnection methods, in this instance step P1, and therefore of circumventing the drawbacks related to this etching step.

Two variants of the method according to the invention will now be described with reference to FIGS. 3 and 4.

These variants correspond to the method step illustrated in FIG. 2d.

In these variants, no annealing at moderate temperature (225° C.-300° C.) allowing the constituent material of the layer 41 to react with the selenium or the sulfur of the layer 7 to create a zone 71 of MoSe₂ or of MoS₂ is carried out.

This is why the constituent material of the layer 41 is not necessarily molybdenum.

On the contrary, the annealing is performed in such a way as to directly convert the metallic constituents present in the layer 42 into photovoltaic material, by virtue of the introduction of Se or S.

The annealing is typically carried out at a temperature of between 400 and 650° C., this temperature being attained with a temperature ramp of strictly greater than 1° C./s and possibly as much as 15° C./s. In a preferred manner, the temperature rise ramp is of the order of 10° C./s and the temperature is of the order of 550° C.

In the case of the method for forming CIGS described in document U.S. Pat. No. 5,436,204, the high-temperature annealing step is carried out during the deposition of the layer 42 comprising metallic precursors.

With steep temperature rise ramps, at the level of the part 400 of the substrate, the material of the layer 41 undergoes significant stresses on account of the expansion of the localized layer 7 made of selenium or sulfur.

These stresses lead to the local breakage of the layer 41 and therefore to the formation of a groove in this layer.

The annealing carried out also leading to the conversion of the layer 42 into the photovoltaic layer 46, this breakage leads to the formation, in the layer 41, of a zone 410 which is filled with photovoltaic material of the same nature as the constituent material of the layer 46. This variant is illustrated in FIG. 3.

Thus, this variant of implementation of the method also leads to the formation, in the layer 41, of a zone 410 exhibiting a more significant resistivity than the remainder of the layer 41. This zone 410 will make it possible also to produce the electrical insulation between two adjacent cells of the photovoltaic module obtained by the method according to the invention.

In the case of the method for forming CIGS described in document U.S. Pat. No. 5,578,503, the high-temperature annealing step is carried out after the deposition of the layer 42 comprising metallic precursors.

With steep temperature rise ramps, at the level of the part 400 of the substrate, the materials of the layer 41 and 42 undergo significant stresses on account of the expansion of the localized layer 7 made of selenium or sulfur.

These stresses lead to the local breakage of the layers 41 and 42 and therefore to the formation of a groove 461 devoid of all material. This variant is illustrated in FIG. 4.

These variants are distinguished from the method step described with reference to FIG. 2d. Indeed, in this case, the value of the temperature rise ramp is on the contrary chosen so as to avoid the appearance of significant stresses within the molybdenum. This allows the reaction of the molybdenum with the sulfur or the selenium so as to obtain a zone 71 made of MoS₂ or MoSe₂.

In these variants, materials other than molybdenum may be used to produce the metallic layer 41. This may in particular be Ni or Pt.

It should be noted that, for these two variants, the other steps of the method are not modified.

Reference is now made to FIGS. 5a to 5f which represent various steps of implementation of another method according to the invention.

As shown by FIG. 5a, in this mode of implementation, a layer 8 of metal is also deposited in a localized manner on the substrate 4. It is in particular copper, or an alloy based on Cu and Se or Cu and S.

Thus, at least one part 401 of the substrate is covered with a metal.

Of course, several parts of the substrate will be able to be covered with a metal, insofar as a plurality of photovoltaic cells are intended to be produced on the substrate 4.

In all cases, the parts 401 of the substrate that are covered with a metal are distinct from the parts 400 covered with selenium or sulfur.

The layer 8 can be deposited by various deposition methods and in particular those mentioned in respect of the layer 7, in regard to FIG. 2a.

FIG. 5b illustrates a method step similar to that illustrated in regard to FIG. 2b and in which a metallic layer 41, in particular made of molybdenum, is deposited on the substrate.

This metallic layer covers the substrate in a uniform manner and coats at one and the same time the localized layer of Se or S and the localized metal layer.

The stack illustrated in FIG. 5b constitutes an intermediate product which can be produced independently of the method steps which will be implemented subsequently.

FIG. 5c illustrates a method step similar to that illustrated in FIG. 2c and in which the precursors, which will lead to the formation of the photovoltaic layer, are introduced in the form of a layer 42.

FIG. 5d illustrates another step of the method in which at one and the same time the localized layers 7 and 8 and the layer 42 are transformed.

Firstly, a step of annealing at a moderate temperature is performed. This annealing step was described with reference to FIG. 2d and will not therefore be described again in detail.

On completion of this annealing step, a zone 71 formed of MoSe₂ or of MoS₂ is formed in the molybdenum layer 41. This zone 71 exhibits a more significant resistivity than the remainder of the layer 41 and thus makes it possible to define the rear-face electrodes 41a and 41b of two adjacent cells and to insulate them electrically.

Subsequent to this annealing step leading to the formation of the zone 71, the temperature of the substrate is further increased so as to carry out a high-temperature annealing, as was described with reference to FIG. 2d, so as to convert the layer 42 into a layer 46 of photovoltaic material.

This annealing will not therefore be described again in detail.

It leads moreover to the diffusion, through the layer 41, of the copper present in the localized layer 8 and to the formation of a zone 460 made of conducting material.

Indeed, on account of the diffusion of copper in the layer 46, the latter locally comprises a percentage of copper greater than that present in the remainder of the photovoltaic layer. When the ratio Cu/(In+Ga) is greater than 1, this leads to the formation of compounds based on Cu and Se or S, known to be conducting. This may in particular involve compounds of the type Cu₂Se or Cu_{1,8}Se or of the type Cu₂S or Cu_{1,8}S.

The thickness of the layer 42 and the quantity of copper introduced by the layer 8 will be tailored so that, in the photovoltaic layer 46, the ratio Cu/(In+Ga) is greater than 1.

By way of example, when the thickness of the CIGS layer 46 is about 1.4 μm with a stoichiometry such that the ratio Cu/(In+Ga) is about 0.8, it will suffice for the thickness of the layer 8 to be about 50 nm, with a width of between 50 and 150 μm and preferably equal to 100 μm, so that the ratio Cu/(In+Ga) is greater than 1 in the zone 460.

Thus, the thickness and the width of the layer 8 will be chosen as a function of the thickness of the layer 46 and of the value of the ratio Cu/(In+Ga) in the layer 46.

In this regard, the diffusion of the copper through the layer 41 begins, in practice, during the annealing step leading to the formation of the zone 71.

However, this diffusion is relatively weak for temperatures of less than 400° C. and it becomes more significant when the temperature of the annealing is between 400 and 650° C.

It may also be noted that, as previously, the annealing step leading to the formation of the zone 71 in the layer 41 can be carried out between the method steps illustrated in FIGS. 4b and 4c, that is to say before the deposition of the layer 42.

Moreover, as described with reference to FIGS. 3 and 4, the method can be implemented without annealing allowing the molybdenum of the layer 41 to react with the selenium or the sulfur of the layer 7 so as to obtain a zone 71 made of MoSe₂ or MoS₂.

In this case, the annealing is performed in such a way as to directly convert the metallic constituents present in the layer 42 into a photovoltaic material, by virtue of the introduction of Se or of S.

According to the method employed, this annealing will lead to the formation of a photovoltaic material zone 410 (FIG. 3) or to the formation of a groove 461 devoid of conducting material and of photovoltaic material (FIG. 4).

These two variants will not be described again in detail.

This high-temperature annealing leads here again to the diffusion of the copper present in the localized layer 8, through the layer 41, so as to form, inside the photovoltaic layer, a zone 460 made of conducting material.

It should also be noted that the diffusion of the copper through the layer 41 is facilitated when the porosity of the layer 41 is significant. The latter can be tailored by modifying the conditions in which the sputtering is carried out.

Thus, when argon is sputtered during the deposition of molybdenum, the sputtering pressure is a parameter of the porosity obtained.

This is why pressure ranges of between 2 mTorr and 15 mTorr will advantageously be able to be used to form the layer 41 by cathodic sputtering. The pressure will preferably be of the order of 10 mTorr.

It should further be noted that on completion of the annealing leading to the formation of the photovoltaic layer 46 and of the zone 460, a part of the copper of the localized layer 8 may still be present in the layer 41.

However, the presence of copper in the layer 41 does not modify the behavior of this layer, insofar as copper is a conducting material, like the remainder of the layer 41.

As will be illustrated in FIG. 4f, the formation of this conducting zone 460 makes it possible to connect the front-face electrode of a given cell to the rear-face electrode of the adjacent cell and therefore to eliminate the etching step P2, conventionally envisaged in the methods of monolithic interconnection.

FIGS. 5e and 5f describe steps of the method which are similar to those that were described with reference to FIGS. 2e, 2f and 2g.

Thus, FIG. 5e shows that three layers are deposited on the layer 46: a layer 43 of n-type semi-conductor, an optional layer 44 of a transparent material and finally, a layer 45 of a transparent and conducting oxide.

FIG. 5f illustrates a last step of the method, in which an etching step corresponding to step P3 is carried out, leading to the obtaining of an opening 412.

FIG. 5f illustrates the path of the charges between two adjacent cells 5 and 6.

The front-face electrode 45a of the first cell 5 makes it possible to collect, at the front face, the electrical charges generated in this cell 5 and to convey them to the rear-face electrode 41b of the adjacent cell 6, through the conducting zone 460 of the layer 46.

Thus, this mode of implementation of the method according to the invention makes it possible to avoid at one and the same time the need to carry out an etching of the type P1 and an etching of the type P2.

Reference is now made to FIG. 6 which illustrates a variant of another step of the method according to the invention, corresponding to FIG. 5e.

FIG. 6 shows that the semi-conductor layer 43 is not deposited in a continuous manner on the photovoltaic layer 46. On the contrary, the layer 43 comprises discontinuities 430, at the level of the zones 460 of the photovoltaic layer 46.

The localized deposition of the layer 43 may for example be carried out by ink-jet. It exhibits the benefit, with respect to the embodiment illustrated in FIG. 5e, of avoiding the addition of a resistance which would stem from the presence of the layer 43, between the electrode 45a and the zone 460.

Complementarily, it should be noted that germanium can also be integrated into the lattice of the CZTS to form a material of the type Cu₂Zn(Sn,Ge)(S,Se)₄, when a selenium and sulfur mixture is introduced.

The metallic constituents forming the layer 42 can also be of the type Cu, Al and In.

The method according to the invention then leads to the obtaining of solar cells whose photovoltaic layer is made of a material of the type Cu(In, Al)(S, Se)₂.

The reference signs inserted after the technical characteristics featuring in the claims are aimed solely at facilitating the understanding of the latter and shall not limit the scope thereof.

1. A method for producing an intermediate product for obtaining a photovoltaic module comprising a plurality of solar cells, this method comprising the following steps:
(a) the localized deposition on a substrate (4) of a layer (7) of a material of the type Se or S, so as to cover at least one part (400) of the substrate,
(b) the deposition, on this localized layer (7), of a layer of conducting material (41), this layer coating the localized layer.

2. The method as claimed in claim 1, in which, during step (a), a metal layer (8) is also deposited locally on the substrate (4) so as to cover at least one part (410) of the substrate, distinct from said at least one part (400) covered with a material of the type Se or S.

3. A method for obtaining a photovoltaic module comprising a plurality of solar cells in a structure in the form of thin layers, which successively comprises a substrate (4), a rear-face electrode (41), a photovoltaic layer (46) obtained by annealing on the basis of metallic precursors and a semi-conductor layer (43), in which:
an intermediate product is produced in accordance with the method as claimed in claim 1, the layer of conducting material (41) forming the rear-face electrode,
an annealing step is carried out, which modifies said localized layer (7) of material of the type Se or S so as to form, in the rear-face electrode (41), a zone (71, 410, 461) exhibiting a more significant resistivity than the remainder of the rear-face electrode, this zone ensuring the electrical insulation between two adjacent cells of the photovoltaic module.

4. The method as claimed in claim 3, in which the annealing step is carried out before the obtaining of the photovoltaic layer, with a temperature ramp of less than or equal to 1° C./s and at a temperature of between 225 and 300° C., for a duration of between 1 and 5 min, said zone (71) of the rear-face electrode being formed of a material resulting from the reaction of the conducting material with Se or S.

5. The method as claimed in claim 3, in which the annealing step is carried out during the obtaining of the photovoltaic layer, at a temperature of between 400 and 650° C., with temperature ramps of strictly greater than 1° C./s and possibly as much as 15° C./s.

6. The method as claimed in claim 5, in which said zone (410) is formed of photovoltaic material.

7. The method as claimed in claim 5, in which said zone (461) is a groove.

8. The method as claimed in claim 3, in which: during step (a) of the method of producing the intermediate product, a layer (7) of a material of the type Se or S is also deposited locally on the substrate (4), so as to cover at least one part (400) of the substrate, distinct from said at least one part (401) covered with metal;
the obtaining of the photovoltaic layer leading to the formation, in this layer, of a zone (460) made of a conducting material, this zone producing the electrical connection between the front-face electrode of a cell and the rear-face electrode of an adjacent cell of the photovoltaic module.

9. A photovoltaic module comprising a plurality of solar cells connected in series on a common substrate (4), each cell comprising a front-face electrode (45), transparent to light, and a rear-face electrode (41), spaced apart from the front-face electrode by a photovoltaic layer (46) and another layer of semi-conductor (43), making it possible to create a pn junction with the photovoltaic layer, in which the rear-face electrodes (41a, 41b) of two adjacent cells (5, 6) are insulated electrically by a zone (71, 410, 461) of the rear-face electrode (41) which is situated between the two cells and which exhibits a more significant resistivity than the remainder of the rear-face electrode.

10. The module as claimed in claim 9, in which said zone (71) is formed of a material resulting from the reaction of the conducting material of the rear-face electrode (41) with an element picked from Se and S.

11. The module as claimed in claim 9, in which this zone (410) is formed of the same material as the photovoltaic layer.

12. The module as claimed in claim 9, in which this zone (461) is a groove.

13. The photovoltaic module as claimed in claim 9 also comprising, in the photovoltaic layer (46) and between two adjacent cells (5, 6), a zone (460) made of a conducting material which produces the electrical connection between the front-face electrode (45a) of a cell (5) and the rear-face electrode (41b) of an adjacent cell (6).

14. An intermediate product for obtaining a photovoltaic module as claimed in claim 9, comprising successively on a substrate (4), a localized layer (7) of Se or S and a layer of conducting material (41) coating this localized layer.

15. The intermediate product for obtaining a photovoltaic module as claimed in claim 13, also comprising, on the substrate (4), a localized layer (8) of a metal which is distinct from the localized layer of Se or S.
